(19) United States
(12) Patent Application Publication
(10) Pub. No.: US 2026/0082730 A1
(43) Pub. Date: Mar. 19, 2026

(54) III-V PHOTOVOLTAIC MULTI-JUNCTION SOLAR CELL

(71) Applicant: AZUR SPACE Solar Power GmbH, Heilbronn (DE)

(72) Inventors: Wolfgang KOESTLER, Heilbronn (DE); Benjamin HAGEDORN, Ilsfeld (DE)

(73) Assignee: AZUR SPACE Solar Power GmbH, Heilbronn (DE)

(21) Appl. No.: 19/398,811

(22) Filed: Nov. 24, 2025

Related U.S. Application Data
(63) Continuation of application No. PCT/EP2024/000031, filed on May 14, 2024.

(30) Foreign Application Priority Data
May 23, 2023 (DE) 10 2023 002 091.5

(51) Int. Cl. H10F 77/67; H10F 10/161; H10F 10/163; H10F 77/20; H10F 77/30

(52) U.S. Cl. CPC H10F 77/67; H10F 10/161; H10F 10/163; H10F 77/211; H10F 77/315

(57) ABSTRACT

A stack-type III-V multijunction solar cell having an upper side and an underside, which includes a substrate layer formed on the underside and a first subcell having a first bandgap on the substrate layer or comprising the substrate layer. A second subcell has a second bandgap and is arranged above the first subcell. A tunnel diode is formed between the first subcell and the second subcell. A finger-shaped first metallic contact region is formed on the upper side. A second metallic contact region is formed over a wide area on the underside. The first contact region comprises multiple metal layers and has a first metal layer comprising silver in a vicinity of the surface and has a titanium layer designed as the uppermost metal layer above the first metal layer to reduce reflection on the upper side. The titanium layer has a thickness of more than 5 nm.

This nonprovisional application is a continuation of International Application No. PCT/EP2024/000031, which was filed on May 14, 2024, and which claims priority to German Patent Application No. 10 2023 002 091.5, which was filed in Germany on May 23, 2023, and which are both herein incorporated by reference.

### BACKGROUND OF THE DESCRIPTION

### Field of the Invention

III-V multijunction solar cells are provided with a stack-type design and have an efficiency of more than 30%, and they are used in outer space and terrestrially in connection with concentrator photovoltaic (CPV) applications.

### Description of the Background Art

For the purpose of an electrical connection of the III-V multijunction solar cells, finger-shaped metal structures are formed on the upper side and a full-surface metal contact is generally formed on the underside.

To reduce the reflection of the sunlight incident upon the III-V multijunction solar cell through the upper side, an anti-reflection layer is formed as the uppermost layer on the upper side.

The finger-shaped metal structures are also designed in such a way that the smallest possible portion of the surface is shaded. The finger-shaped metal structures furthermore include a thin gold layer as the cover layer. The sunlight striking the cover layer is almost completely reflected hereby. The highest possible reflection of the cover layer is particularly important to reduce the heating of the III-V multifunction solar cell. The cover layers generally have a reflection of more than 80% in the visible as well as in the infrared spectral range. It is understood that the efficiency of the multijunction solar cell decreases as the heating increases; a reduction of the efficiency is to be avoided as much as possible.

US 2015/034155 A1 and US 2015/034152 A1 each describe III-V multiple solar cells having a finger-shaped metallic contact system with an ARC layer on their upper side. From DAKKA A ET AL: “OPTICAL STUDY OF TITANIUM DIOXIDE THIN FILMS PREPARED BY R. F. SPUTTERING,” MOROCCAN JOURNAL OF CONDENSED MATTER, Vol. 2, No. 2, 1999, pp. 1-3, XP002595710 and from CHENG QIANG ET AL: “Radiative Properties of Ceramic Al₂O₃, AlN, and Si3N4: I. Experiments”, INT. JOURNAL OF THERMOPHYSICS, Vol. 37, No. 6, May 3, 2016, pp. 1-16, XP035682876, the optical properties of different layers are known.

### SUMMARY OF THE INVENTION

It is therefore an object of the present invention to provide a device which refines the prior art.

The object is achieved, according to an example, by a stack-type III-V multijunction solar cell having an upper side and a underside is provided, which includes a substrate layer formed on the underside.

The substrate layer has an underside and an upper side, the underside of the substrate layer corresponding to the underside of the III-V multijunction solar cell.

A first subcell can be formed on the substrate layer. Alternatively the first subcell is formed on the upper side of the substrate layer as part of the substrate layer. The first subcell has a first bandgap.

A second subcells having a second bandgap can be arranged above the first subcell, the second bandgap being larger than the first bandgap.

A tunnel diode can be formed between the first subcell and the second subcell.

A finger-shaped first metallic contact region can be formed on the upper side. It should be noted that the first metallic contact region also comprises a few smaller metallic surfaces in addition to the vastly predominant finger-shaped structures. A second metallic contact region formed over a wide area is formed on the underside. The second metallic contact region preferably covers at least 70% of the total surface area of the underside.

The first contact region comprises multiple metal layers, a silver layer being a main constituent of the first contact region.

An absorbent layer having a thickness of more than 5 nm and less than 750 nm can be formed above the silver layer and connected in a materially bonded manner to the silver layer.

An advantage of the materially bonded arrangement of the absorbent layer on the silver layer is a reduction of the manufacturing costs, in that no further layers are formed between the silver layer and the absorbent layer.

An intermediate layer can be formed between the silver layer and the absorbent layer. One advantage of intermediate layers is that an adherence of the cover layer may be improved. In one refinement, the intermediate layer may also be provided with a highly matte, i.e. slightly rough, surface, so that the cover layer may also be easily provided with a matte design.

The absorbent layer can have an average absorptivity for solar radiation of more than 0.5.

It should be noted that the term absorbent layer designates a layer which has a reflection coefficient of less than 80% or less than 60% or less than 30% or less than 15% or less than 10% in at least a portion of the light spectrum, in particular in the infrared wavelength range and/or the visible portion of the wavelength range. It is understood that the reflection coefficient depends on the wavelength, i.e. on the frequency, and relates in each case to reflective surfaces, the numeric values in this case relating primarily to an average reflection coefficient for the spectral range of sunlight.

It should be noted that metals such as gold or silver generally have a reflection coefficient greater than 80% in the infrared wavelength range.

It should furthermore be noted that the reflection coefficient in metals is more than 80% even well into the blue or ultraviolet spectral range, depending on the position of the plasma edge according to the Drude-Lorenz theory. Small absorption bands, which are responsible for the colors of metals, are negligible here.

In other words, the absorbent layer has a frequency-dependent absorption coefficient α as an intrinsic characteristic, absorption coefficient α indicating the share of the incident light which is absorbed by the layer. It should be noted that the term absorptivity a and the term absorption coefficient α are used synonymously.

Directed spectral absorptivity a indicates the fraction of the frequency from the incident spectral irradiance due to the angle and direction, which is absorbed by a surface element of the body, using the following relationship:

$${α}_{v}^{i} ( ( β . φ , v , T ) = \frac{{K}_{Ω v}^{abs} ( β , φ , v )}{K Ω v ( β , φ , v )}$$

In the present case, an average absorptivity for the entire wavelength range or frequency range of the sunlight is indicated in reference to the aforementioned equation. The average absorptivity is greater than 0.5 or greater than 0.7 or greater than 0.8, oxidized copper having an average absorptivity of approximately 0.7 and soot having an absorptivity of approximately 0.96.

The color of the absorbent layer can be in a range between a matte dark gray tone and a matte deep black, the color specifications relating to the RAL system in the range of the 6000 to the 8000 numbers.

It is understood that the absorbent layer may only be formed on the first contact region.

The absorbent layer comprises or is made solely from an organic or anorganic material.

The absorbent layer can comprise a metal layer or a metallic layer, or the absorbent layer can be made up of a metal layer or a metallic layer.

The absorbent layer can have a material composition other than that of the underlying silver layer or the underlying intermediate layer.

Each of the III-V multijunction solar cells can have a surface area of more than 50 mm² or more than 150 mm². In another refinement, each of the III-V solar cells has, in a first approximation, the surface area of a semiconductor wafer having a diameter of 100 mm² or a diameter of 150 mm² or, in a first approximately, the surface area of half of the semiconductor wafer.

It should be noted that the III-V multijunction semiconductor cells comprise not only two subcells but, in particular, at least three or four subcells and are usually manufactured epitaxially on a germanium substrate or on a GaAs substrate by means of an MOVPE process.

The subcell having the largest bandgap is formed on the upper side and generally comprises am (Al)InGaP compound or is made up of an (Al)InGaP compound.

An advantage is that the absorption of the first contact region may be increased by means of the cover layer made from an absorbent layer without an increase in the electrical resistance of the finger-shaped contact regions.

In particular, with the aid of the increased heat input, the III-V multijunction solar cells may also be used for combined applications, i.e., for generating electricity while simultaneously generating heat in the area of power generation. Photoelectric and solar thermal combinations of this type have a particularly high total efficiency in a range above 50%.

In other words, the heat input into the III-V multijunction solar cell may be increased with the aid of the absorbent layer. It is understood that III-V multijunction solar cells have a high efficiency even at temperatures above 100° C., in contrast to silicon solar cells.

A further advantage is that the manufacturing costs may be lowered in that the uppermost layer is no longer designed as a gold layer in the first contact region.

The absorbent layer and/or the intermediate layer can be designed as electrically conductive layers. It should be noted that the two layers differ from each other and in relation to the silver layer with regard to the stoichiometry and/or the materials.

The intermediate layer can have a thickness between 5 nm and 250 nm or a thickness between 10 nm and 30 nm.

The intermediate layer can comprise a metal, or the intermediate layer is made up of a metal.

A passive or active cooling can be formed on the back side to more easily remove the slightly greater heat input due to the increased absorption of the first metal region.

The total efficiency of the III-V multijunction solar cells increases hereby, due to a photoelectric efficiency of more than 28% or more than 30% or more than 35% or more than 40% and, in addition, a thermal efficiency of more than 5% or more than 15% or more than 25% or more than 30% and less than 70% or less than 60%.

A further advantage is that the silver layer may be reliably passivated with the aid of the absorbent layer, for example a titanium layer or a layer comprising titanium. Another advantage is that the manufacturing costs may be reduced in that the absorbent layer as a titanium layer makes the previous passivation of the silver layer with the aid of gold unnecessary.

An anti-reflection layer can be arranged above the absorbent layer, the anti-reflection layer being connected to the absorbent payer in a materially bonded manner.

The silver layer can have a thickness greater than the thickness of the absorbent layer at least by a factor of 10.

The silver layer can have a quadrangular cross-section, the ratio between two side lengths of the quadrangle being in a range between 0.5 and 2.

A contact metal system can be arranged under the silver layer, the contact metal system having a thickness smaller than that of the silver layer at least by a factor of 5 or by a factor of 10 or by a factor of 20.

The silver layer can be electrically connected to the surface of the III-V multijunction solar cell with the aid of the contact metal system. In one refinement, the contact metal system is formed only beneath the silver layer. An electrically conductive cover layer is formed under the contact system.

The cover layer can comprise an (In) GaAs compound. A window layer can be formed under the cover layer, the window layer having a different stoichiometry than the cover layer. Further, the window layer can comprise or is made of an InAlP compound.

The cover layer may only be formed beneath the first contact region.

The thickness of the silver layer can be in a range between 50 nm and 500 nm or in a range between 100 nm and 400 nm.

The silver layer can have a quadrangular cross-section with a base surface and a first side surface and a cover surface and a second side surface. In one refinement, the ratio of the sum of the length of the two side surfaces to the length of the cover surface is in a range between 0.3 and 3 in cross-section.

The absorbent layer can be formed in a materially bonded manner on the surface of the silver layer at the two side surfaces. The anti-reflection layer is furthermore formed in a materially bonded manner on the surface of the absorbent layer.

The absorbent layer may comprise or is made up of a metallic layer or a metal layer.

The metal layer can comprise or is made up of a titanium layer or a black nickel layer, the titanium layer or the black nickel layer having a thickness of more than 5 nm. In an example, the thickness of the black nickel layer and/or the thickness of the titanium layer is/are less than 300 nm or less than 100 nm or less than 50 nm.

It should be noted that the term titanium layer also includes a layer made up of pure titanium as well as a layer made up of a titanium alloy as well as a titanium compound.

It should be understood that the share of the element titanium is greater than 50% in a layer made up of a titanium alloy or a titanium compound. In other words, the main constituent of the particular alloy or compound is the element titanium.

A cover surface of the silver layer and two side surfaces directly connected to the cover surface can be completely covered by the titanium layer or the layer comprising titanium.

The titanium layer or the layer comprising titanium can have a thickness in a range between 10 nm and 300 nm or in a range between 20 nm and 100 nm or a thickness of less than 150 nm.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a cross-sectional view of a solar cell structure having a stack-type III-V multijunction solar cell in an example; and

FIG. 2 shows a cross-sectional view of a solar cell structure having a stack-type III-V multijunction solar cell in an example.

### DETAILED DESCRIPTION

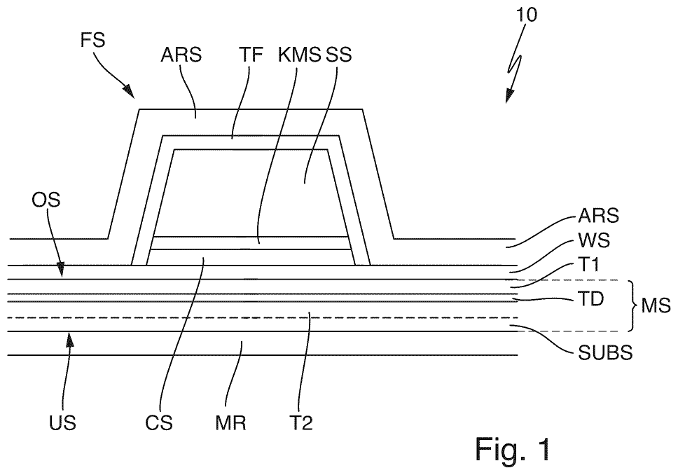

The illustration in FIG. 1 shows a cross-sectional view of a solar cell structure 10 having a stack-type III-V multijunction solar cell MS in an example. III-V multijunction solar cell MS has an upper side OS and an underside US.

A substrate layer SUBS is formed on underside US of III-V multijunction solar cell MS. A first subcell T1 is arranged on substrate layer SUBS. Alternatively, substrate layer SUBS comprises first subcell T1. First subcell T1 has a first bandgap. A second subcell T2 having a second bandgap is arranged above the first subcell. The second bandgap is larger than the first bandgap. A tunnel diode TD is formed between first subcell T1 and second subcell T2.

In the present case, III-V multijunction solar cell MS comprises two subcells T1 and T2. However, it is understood that III-V multijunction solar cell MS also comprises more than two subcells, in particular three or more subcells.

A finger-shaped first metallic contact region is formed on upper side OS, the first contact region comprising a multiplicity of finger-shaped structures FS for a low-resistance electrical connection of upper side OS. Finger-shaped structures FS are provided with a narrow design for the purpose of minimizing the shading of upper side OS.

A window layer WS formed over the entire surface is arranged directly on upper side OS of III-V multijunction solar cell MS. An electrically conductive cover layer CS is formed between window layer WS and the first contact layer designed as finger-shaped structure FS. It should be noted that cover layer CS is formed only beneath finger-shaped structure FS.

A second metal contact region MR is formed over a wide area on underside US, underside US being almost completely covered by second contact region MR.

The first contact region, or finger-shaped structures FS, comprises multiple metal layers, a layer made up of a silver layer SS or a silver layer SS being designed as the main constituent of finger-shaped structures FS. Silver layer SS has a quadrangular cross-section.

A contact metal system KMS is formed between silver layer SS and cover layer CS, contact metal system KMS being connected in a materially bonded manner to cover layer CS and formed only beneath silver layer SS. Silver layer SS is connected in a materially bonded manner to contact metal system KMS on an underside.

To reduce reflection on upper side OS, a titanium layer TF or a layer TF comprising titanium, for example, is formed above silver layer SS as an absorbent layer, titanium layer TF or layer TF comprising titanium being connected in a materially bonded manner to silver layer SS.

In an example, a black nickel layer is designed as the absorbent layer.

However, it is understood that an anorganic or an organic layer may be formed on silver layer SS as the absorbent layer.

Silver layer SS, which has a cover surface and two side surfaces directly adjacent to the cover surface, is completely covered by titanium layer TF designed as the absorbent layer or a layer TF comprising titanium. Titanium layer TF or layer TF comprising titanium has a thickness of more than 5 nm.

Anti-reflection layer ARS is formed on finger-shaped structure FS and on window layer WS formed between the finger-shaped structures. Anti-reflection layer ARS is connected in a materially bonded manner to titanium layer TF or layer TF comprising titanium and to window layer WS.

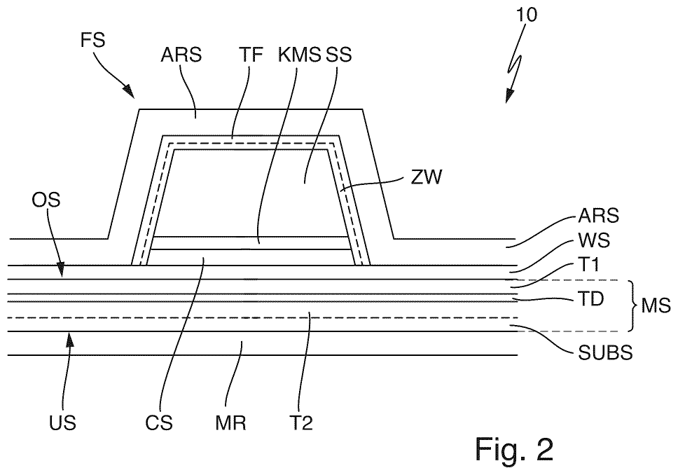

A cross-sectional view of a solar cell structure having a stack-type III-V multijunction solar cell is shown in an example in the illustration in FIG. 2.

Only the differences from the example in FIG. 1 are explained below.

An intermediate layer ZW is formed between silver layer SS and the absorbent layer.

In the present case, the intermediate layer is provided with an electrically conductive design and comprises a metal or is made up of a metal.

Intermediate layer ZW is connected in a materially bonded manner to silver layer SS and the absorbent layer.

In an example, the intermediate layer comprises multiple individual layers in the form of a layer stack.

As already noted in connection with the remarks on the example in FIG. 1, the absorbent layer is designed as a titanium layer or as a black nickel layer.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A stack-type III-V multijunction solar cell having an upper side and an underside the stack-type III-V multijunction solar cell comprising:
a substrate layer formed on the underside;
a first subcell having a first bandgap on the substrate layer or comprising the substrate layer;
a second subcell having a second bandgap and arranged above the first subcell, the second bandgap being larger than the first bandgap;
a tunnel diode formed between the first subcell and the second subcell;
a finger-shaped first metallic contact region formed on the upper side, the first metallic contact region comprising at least two metal layers and having a silver layer as a main constituent;
a second metallic contact region formed over a wide area on the underside; and
an absorbent layer having a thickness of more than 5 nm and less than 750 nm formed above the silver layer and connected in a materially bonded manner to the silver layer and/or an intermediate layer formed between the silver layer and the absorbent layer to increase a heat input via the absorbent layer formed on the first contact region,
wherein the absorbent layer and/or the intermediate layer are electrically conductive layers, and
wherein the absorbent layer has an average absorptivity for solar radiation of more than 0.5.

2. The stack-type III-V multijunction solar cell according to claim 1, wherein the absorbent layer is connected in a materially bonded manner to the silver layer or to the intermediate layer as a titanium layer or as a layer comprising titanium.

3. The stack-type III-V multijunction solar cell according to claim 1, wherein an anti-reflection layer is arranged above the titanium layer or the layer comprising titanium, and wherein the anti-reflection layer is connected in a materially bonded manner to the titanium layer.

4. The stack-type III-V multijunction solar cell according to claim 1, wherein the silver layer has a thickness greater than that of the titanium layer or the layer comprising titanium at least by a factor of 10.

5. The stack-type III-V multijunction solar cell according to claim 1, wherein a contact metal system is arranged under the silver layer, wherein the contact metal system has a thickness that is smaller than that of the silver layer by a factor of 5, and wherein the first contact region is electrically connected to the surface of the III-V multijunction solar cell via the contact metal system.

6. The stack-type III-V multijunction solar cell according to claim 1, wherein the silver layer has a quadrangular cross-section with a base surface and a first side surface and a cover surface and a second side surface.

7. The stack-type III-V multijunction solar cell according to claim 6, wherein the ratio of a length of the first and second side surfaces to the length of the cover surface is in a range between 0.3 and 3 in cross-section.

8. The stack-type III-V multijunction solar cell according to claim 6, wherein, at the first and second side surfaces, the titanium layer is formed in a materially bonded manner on the surface of the silver layer, and wherein the anti-reflection layer is formed in a materially bonded manner on the surface of the titanium layer or the layer comprising titanium.

9. The stack-type III-V multijunction solar cell according to claim 1, wherein the absorbent layer is designed as a titanium layer or a layer comprising titanium or as a layer including black nickel or made up of black nickel.

10. The stack-type III-V multijunction solar cell according to claim 9, wherein the titanium layer or the layer comprising titanium has a thickness of more than 5 nm or a thickness in a range between 10 nm and 300 nm or in a range between 20 nm and 100 nm or a thickness of less than 150 nm.

11. The stack-type III-V multijunction solar cell according to claim 8, wherein the titanium layer comprises a layer made up of pure titanium or a titanium alloy or a titanium compound, and the titanium alloy is the share of the element titanium of more than 50% in each case.

12. The stack-type III-V multijunction solar cell according to claim 1, wherein the intermediate layer is electrically conductive.

13. The stack-type III-V multijunction solar cell according to claim 1, wherein the average absorption coefficient is greater than 0.7.

14. The stack-type III-V multijunction solar cell according to claim 1, wherein the absorbent layer is not arranged between the finger-shaped first metallic contact regions on the upper side.

15. The stack-type III-V multijunction solar cell according to claim 1, wherein the absorbent layer completely covers the cover surface of the silver layer and two side surfaces directly connected to the cover surface.

16. The stack-type III-V multijunction solar cell according to claim 1, wherein the intermediate layer comprises a metal, or the intermediate layer is made up of a metal.

17. A use of the stack-type III-V multijunction solar cell according to claim 1, for generating electricity while simultaneously generating heat in the area of power generation.
